(19) United States
(12) Patent Application Publication
(10) Pub. No.: US 2005/0113947 A1
(43) Pub. Date: May 26, 2005

(54) Programmable system panel apparatus and method

(75) Inventors: Raymond J. LeBlanc, Bristol, CT (US); Angelo S. Arcaria, Wethersfield, CT (US)

Correspondence Address: BAKER & HOSTETLER LLP;Washington Square, Suite 1100, 1050 Connecticut Avenue, N.W., Washington, DC, 20036, US

(73) Assignee: Edwards Systems Technology, Inc.

(21) Appl. No.: 10/716,660

(22) Filed: Nov. 20, 2003

(51) Int. Cl. G06F 17/00; H04B 1/00; H03F 21/00

(52) U.S. Cl. 700/94; 381/119; 381/120

(57) ABSTRACT

A digitally enabled speaker amplifier system not only offers substantial numbers of analog loudspeaker outputs in response to a command to emit a selected tone or alarm signal but also supports regionalized and unit-by-unit control of the selected signals. The functionality disclosed herein further allows external command signals to configure a master system panel that controls the speaker amplifier system.

### FIELD OF THE INVENTION

The present invention relates generally to paging, signaling, and annunciator systems. More particularly, the invention relates to automated initialization of remote paging and signaling.

### BACKGROUND OF THE INVENTION

Annunciator and paging systems within such facilities as factories, office buildings, parks, schools, and the like can use electrically activated bells as well as speaker-generated tones to announce normal periodic events such as breaks, shift changes, and other non-emergency events. Some such systems, using mechanical bells, are commonly limited to a single sound, while others, using speakers and driven from a central audio tone source, can emit a range of sounds.

Some paging, signaling, and annunciator system designs use an individual loudspeaker at each of a multiplicity of locations. In some versions, they are wired in parallel, with each speaker transformer-isolated to permit high transmitter signal voltage at low current, which can reduce copper losses. Other designs may use signals sent from a central source at comparatively low levels, with speaker amplifiers equipped with power supplies driven by local AC or DC power. Systems with multiple zones to be signaled at different times or under different circumstances may be directly wired by zone from a shared control panel. Speaker amplifiers wired individually back to a control panel may be activated individually using switches. Volume control may be realized using a central attenuator or an attenuator at each speaker or speaker amplifier.

In addition to analog systems, digitally enabled speaker systems can include direct addressing of individual speaker amplifiers through a signal distribution system, so that individual speaker amplifiers can recognize their own addresses and respond appropriately. Conventional speaker systems typically employ RS-485, which is a standard controlled by the Electronics Industry Association (EIA). RS-485 is a two-wire transmission line communication bus that uses a differential serial data stream for communication between one talker at a time and multiple listeners. RS-485 can be configured to be sufficiently flexible to permit each listener to reply when commanded to do so and to permit multiple talkers to talk in turn, using a scheduling protocol to avoid bus contention. Speaker systems utilizing RS-485 are typically programmed by manually entering via a keypad a limited set of character strings a repetitive manner. Duplication of sequences to be transmitted to multiple speaker amplifiers and to subordinate control panels by copy-and-paste methods is commonly not available.

Existing systems of the types described, when used for emergency and evacuation applications in the United States, are generally permitted by local fire codes only if approved by Underwriters Laboratories, Inc., a private certification organization; similar certification organizations exist in most countries, and provide approvals on a country-by-country basis.

Existing certified systems of the types described have been limited to manual operation of the system configuration task, which can be time-consuming and error-prone in complex installations. The difficulty of configuration of such systems can in turn drive architectural and even safety decisions concerning the degree to which complexity may be designed in, so that a system that is useful and practical, but complex, may be avoided in preference to a system that is less useful but less complex.

Therefore, it would be desirable to have a speaker amplifier system with increased capability and flexibility, to take advantage of the opportunities offered by incorporating computer technology into speaker amplifier systems to a greater extent than has been done heretofore.

### SUMMARY OF THE INVENTION

The forgoing needs are met, to a great extent, by the present invention, which in some embodiments provides a configuration gateway for system panels, which gateway may be installed for example in a system panel that is able to receive and transmit digital control transmissions. A preferred embodiment includes a set of commands augmenting those of a previous style of system panel in order to allow that system panel's configuration functions to be commanded for execution from an external source. Setup activity to configure system panels, both for tones and for audio signals such as voice and radio, can configure system panels for output individually, and, through the system panels, can configure digitally enabled speaker amplifiers. The interface allows for system expansion and includes direct communication with individual system panels.

In one aspect, a master system panel comprises an analog audio signal transmitter, a digital signal transceiver, and a command execution facility comprising a processor, wherein the command execution facility is capable of accepting and executing a command received via the transceiver.

In another aspect, a programmable speaker amplifier control system comprises a master system panel, a speaker amplifier, and a communication subsystem interconnecting the master system panel and the speaker amplifier.

In yet another aspect, a programmable speaker amplifier system comprises processing means for processing electronic signals, communicating means for communicating between the processing means and a speaker amplifier, and configuring means for configuring the processing means in response to externally applied signals.

In still another aspect, a process for configuring a programmable speaker amplifier system comprises the steps of communicating between an external signal source and a system panel, and configuring a system panel.

There have thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is an overall block diagram of a speaker amplifier system according to this invention.

FIG. 2 is an exemplary view of a table of commands augmenting System Panel functionality.

FIG. 3 is a flowchart of an exemplary process of this invention.

### DETAILED DESCRIPTION

The invention will now be described with reference to the drawing figures, in which like reference numerals refer to like parts throughout. Embodiments in accordance with the present invention provide a method and apparatus for configuring at least one control panel in a speaker amplifier system by transfer of control of that control panel to a control processor.

It should be appreciated that the terms annunciator and speaker amplifier are typically differentiated by the presence either of a tone generator—with or without a voice recording function—in annunciators, or of an analog audio amplification capability in speaker amplifiers. Both device types can be configured to communicate with other system elements through communications apparatus such as RS-485, although so-called dumb speaker amplifiers may accept only analog input and may lack RS-485 interface capability. The term speaker amplifier is broadly used herein in accordance with the device styles to which the present invention can be applied. The term digitally enabled, as used herein, refers to the transmission and reception of digital electrical signals, serial in organization in the exemplary system, that contain synchronization, address, data, and other bit sequences to command at least one electronic device external to the transmitting device. In the exemplary system, any digital signals are communicated on separate wires from any analog signals passed from a source device to a destination device.

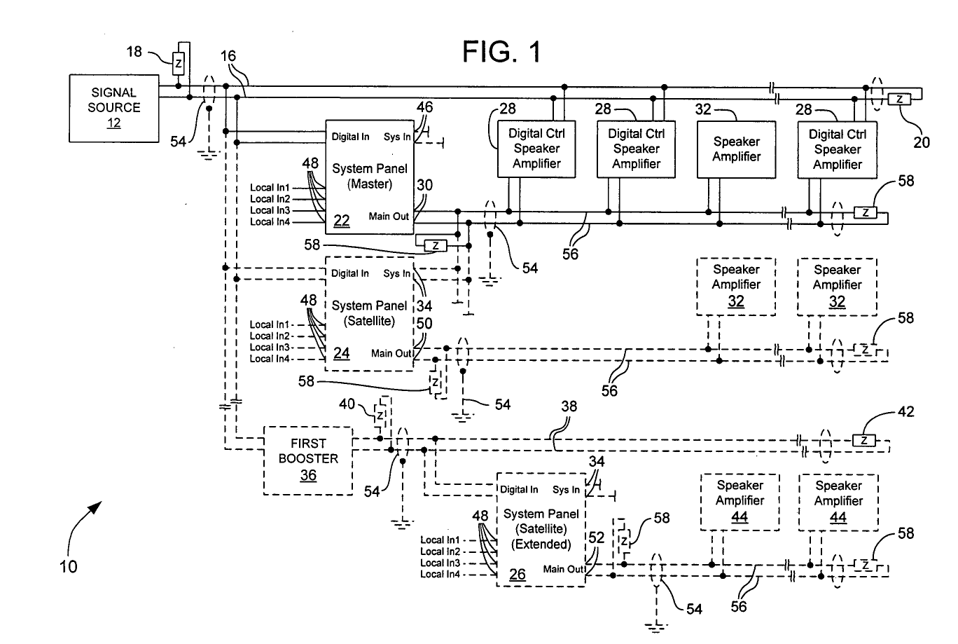

FIG. 1 illustrates an exemplary embodiment of the present invention, an exemplary speaker amplifier system 10 in which a Signal Source 12 generates signals emitted via an integral transceiver (not shown). The transceiver in the exemplary Signal Source 12 can transmit and receive RS-485, thereby enabling the signals to be carried outward on a transmission line 16. The Signal Source 12 may further comprise a human interface subsystem and a nonvolatile storage subsystem as well as the communications subsystem herein described. The transmission line 16 may be a differential, controlled-impedance transmission line and may feature a beginning-of-line termination load 18 and an end-of line termination load 20. The signals may be detected by the receiver section of a Master System Panel 22, by optional Satellite System Panels 24 or 26, and by optional digitally enabled speaker amplifiers 28. Since the transmission line 16 is capable of being bidirectional, response signals transmitted by the Master System Panel 22 can propagate back on the transmission line 16 to the Signal Source 12. The termination loads 18 and 20, by attenuating reverberation, can extend bidirectional communication along a longer transmission line 16.

The exemplary Master System Panel 22 can have an analog output, termed Main Out 30, which can feed the analog inputs of any analog speaker amplifiers 32, connected via signal lines 56, as well as the Sys In 34 analog input lines of any Satellite System Panels 24 or 26 in the system. Satellite System Panels 24 and 26, which devices share the bus 16 with the Master Control Panel 22 and the Signal Source 12, may be configured using the exemplary embodiment described herein, as may be any digitally enabled speaker amplifiers 28, provided the digitally enabled speaker amplifiers 28 recognizes at least one of the commands the Signal Source 12 is capable of transmitting. A Satellite System Panel 24 employed in the exemplary apparatus may similarly drive a multiplicity of analog Speaker Amplifiers 32 by way of its Main Out 50 analog audio output port.

FIG. 1 further shows an optional First Booster 36 connected to the bus 16, driving an extended transmission line 38, which can be equipped with extended-line termination loads 40 and 42 to permit communication with at least one Extended Satellite System Panel 26. The range and number of devices configured into a system are not hardware-limited to the use of a single Extended Satellite System Panel 26, but may expand to the address limits of the underlying System Panel controller electronics, as realized in firmware within the System Panels 22, 24, and 26. Moreover, further development of System Panel controller firmware may permit extension further still. An Extended Satellite System Panel 26 employed in the exemplary apparatus may drive a multiplicity of Extended Analog System Speaker Amplifiers 44 by way of its Main Out 52 analog audio output port.

The Signal Source 12 shown in FIG. 1 may include a differential transceiver. The use of the differential transceiver type can increase the noise immunity of the network connecting the Signal Source, the transmission line 16, the Master System Panel 22, any Satellite System Panels 24, any directly-connected, digitally enabled speaker amplifiers 28 and 32, any boosters 36, and various termination loads 18, 20, 40, and 42. Shielding 54 on the digital signal lines 16 and 38 may reduce noise, further increasing effective digital transmission range. Analog lines 56 driving speaker amplifiers can likewise benefit from shielding 54 and termination loads 58.

A representative multi-drop—that is, having several separate and physically distinct loads wired in parallel—differential transceiver system according to the preferred embodiment can conform to EIA standard RS-485. Alternative transceiver hardware embodiments that can have satisfactory performance under some design regimes include IEEE-1394, generally referred to as FireWire®, IEEE-802 Local and Metropolitan Area Networks, including IEEE-802.3 Ethernet®, and military standard MIL-STD-1553 transformer-coupled differential systems, as well as MIL-STD-1773 and other fiber optic-based systems, radio transmissions, and modulation on power lines.

An audio input to the Sys In port 46 of the Master System Panel 22 may be fed from any of a variety of signal sources. An exemplary Master System Panel 22 may accept input signals over a wide voltage and power range. An exemplary system using a Master System Panel 22 may depend on analog audio signal amplifiers within the Master System Panel 22 to provide distributed, low-level signals for on the order of 200 Speaker Amplifier devices 28 and 32, each of which devices can boost this signal to audible levels using, for example, local AC power to power an amplifier within each Speaker Amplifier 28 or 32.

Each exemplary System Panel, Master 22 or Satellite 24, in a system according to the inventive apparatus may be equipped with one or more circuits to accept a multiplicity of switch closures on inputs, shown as Local In1 through Local In4 48 in FIG. 1, hereinafter generalized as Local In(n), closure of each of which can cause the affected System Panel 22 or 24 to output a specific preprogrammed or preselected analog audio signal on its Main Out terminals 30 or 50. As dictated by internal hardware, each Speaker Amplifier 32 may be equipped to boost this signal to an audible level.

Each digitally enabled Speaker Amplifier 28 may also boost this signal to an audible level, with the added feature of permitting control by the System Panel. For example, if programming of a digitally enabled Speaker Amplifier 28 using local setup at the System Panel, or remotely, enables the digitally enabled Speaker Amplifier 28 to recognize that it has been assigned to the zone to which the specific Local In(n) input has likewise been assigned, and if audio output has been enabled, then the digitally enabled Speaker Amplifier 28 can emit the selected output.

An external source, such as a microphone or radio receiver, or an internal source, such as internet radio or prerecorded programming material accessed by the Control Processor 12, can be the program source for sound to be emitted by selected Speaker Amplifiers 28 and/or 32 fed by Sys In 46 or 34 analog audio input terminals.

Speaker amplifier products that can be used with the exemplary system 10 commonly use loudspeakers to communicate messages, such as tones, prerecorded voice messages, or other forms of audible signals. Lights such as strobe lights, light emitting diodes, or incandescent lamps can augment the communication function of the loudspeakers. Short-range radio transmitters can similarly be used to send sounds, vibrations, or other signals to receivers worn on the persons of individuals who may be unable to detect other speaker amplifier signals. Signals from speaker amplifiers can similarly be used to activate functional features that may be needed under special circumstances, such as the release of electromagnetically held doors.

The Signal Source 12 can coordinate command and control of these various, and other, operations via computer technology, for example. It should be appreciated that the Signal Source 12 may be realized through the use of a desktop computer, for example. These processing functions can also be accomplished using a microcontroller, microprocessor, or other logic controlling device, as desired.

The exemplary system herein described is based in part on use of at least one System Panel (SP) that can provide control of digitally enabled Speaker Amplifiers (DESAs) 28 by transmitting, for example, RS-485 signals that the speaker amplifiers can detect, including commands that allow analog audio tone emission. In some systems, a first SP may be designated and configured as a Master System Panel (MSP) 22, while one or more others may be designated and configured as Satellite System Panels (SSPs) 24.

The exemplary MSP 22 described herein may incorporate a computing device that performs the functions of previous MSPs, to which may be added a series of additional functions that permit the exemplary MSP 22 to suspend its control over subordinated devices such as system SSPs 24 and DESAs 28, halt any normal signal transmissions, and wait for further external input. The suspension may be initiated through operation of front-panel controls on the MSP 20 where security requirements so dictate. The additional functions in the exemplary MSP 22 can be decoded by the computing device in the MSP 22 in the same fashion as responses by SSPs 24 and DESAs 28 to outgoing commands can be encoded thereby.

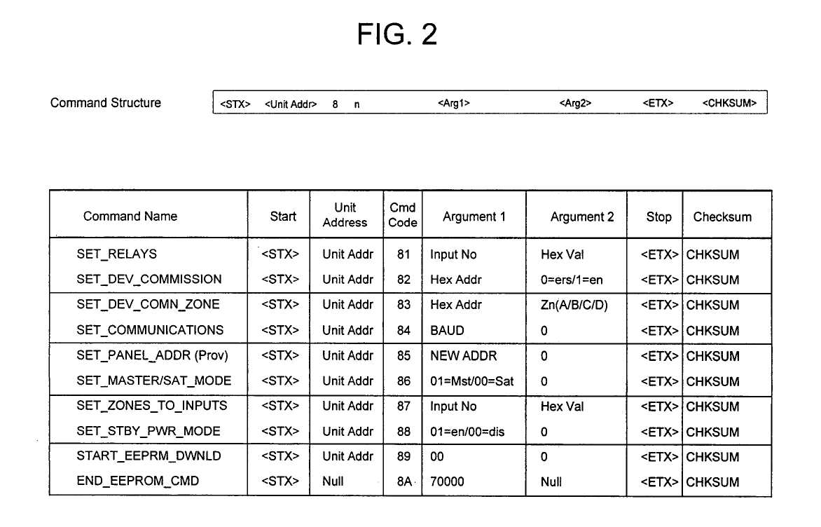

FIG. 2 illustrates an exemplary set of functions that can be added to an exemplary MSP 22 to allow it to be configured from an external Signal Source 12. Functions sufficient to permit external configuration may include commands to change the closure status of mechanical relays, such as the exemplary command 81(hex), commands to change the contents of storage locations within the MSP 22, such as the exemplary commands 82-88(hex), and commands to output the contents of those locations, such as the exemplary command 89(hex). Another command type can terminate external control, restoring the MSP 22 to normal operation until it is again commanded from its own front panel to halt and give up control, such as the exemplary command 8A(hex).

Operation in the described mode potentially permits the Signal Source 12 to transmit ordinary MSP 22 commands, which may be received by other devices in the system while the MSP 22 is set offline. This may allow an SSP 24 or a DESA 28 to be reconfigured without manual entry of setup commands from the MSP 22.

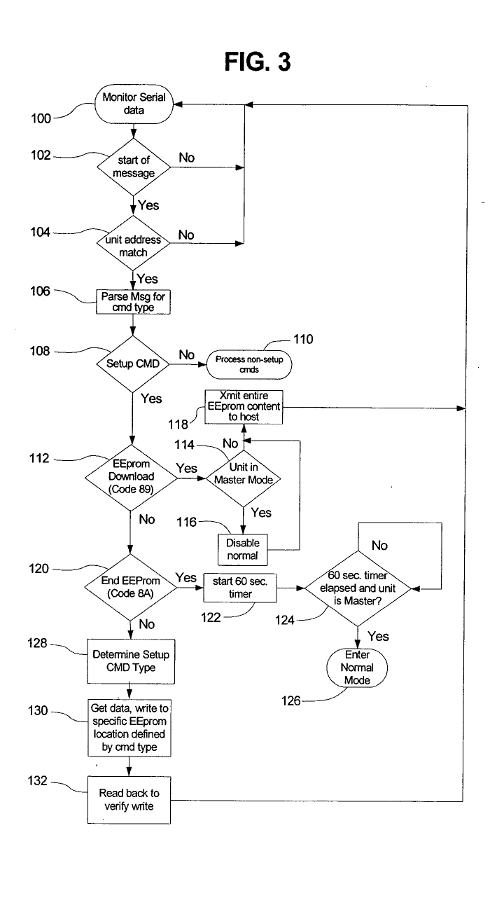

FIG. 3 illustrates an exemplary process that can take place within the controller subsection of an SP, and can result in execution of at least one of the instructions related to system setup from an external Signal Source 12. In the illustrated process, activation of the routine begins by a call to the Monitor Serial Data state 100. This jump may be invoked by an MSP 20 from the MSP 20 front panel controls as noted, after which incoming signals on the RS-485 input/output line 16 may be recognized as commands to the MSP 20.

Message arrival 102 can initiate bitwise analysis; if a recognizable transmission start sequence arrives and is followed by the MSP's address 104 then the remainder of the message can be captured and parsed 106 for an identifiable command. If the bits following the transmission start sequence are not in the range 80(hex) to 8F(hex) 108, then the message is not a setup command, so the functionality herein described is not called for and another process sequence may be invoked 110 instead. If the message is a setup command 108, then the message is further parsed. If the message is a download command, i.e., a “read current configuration” command 112, then an additional level of disablement may be invoked 116 if the unit is an MSP 114, after which data transfer proceeds 118, with the MSP 20 returning to monitor mode 100 thereafter. Similarly, if the command directs termination of the setup mode 120, then after a hold 122, 124, the routine returns to normal mode 126 and the MSP 20 ceases responding to Signal Source 12 commands.

A Signal Source 12 message that is not involved in the above procedures can be further parsed 128, in which case the bit definitions per FIG. 2 determine which configuration elements are written to 130, then verified 132, after which the MSP 20 halts again, still in setup mode, waiting for the next message 100.

Any other useful instructions can be added to an MSP 20 that are supported by its architecture. As in the case of the present invention, approval for such additional instructions from certification organizations such as Underwriters Laboratories for the U.S. may be sought if there is intent to have the final product incorporated into fire and evacuation safety systems. Like the present invention, such additional instructions may be designed so that the final product is fully compatible with unenhanced versions of the same product, which allows users to build the enhanced product into new systems identical to earlier systems, or to build enhanced systems, as desired.

It is obvious that architecture enhancements to MSPs 22 can also be made, which may potentially render new systems incompatible in part with earlier ones. Such enhancements may include for example communication modes, address bit counts not decodable by the earlier controller hardware, different numbers of zones, relays, switch inputs, or tone options, and other features that can be so designed as to allow restricted use with earlier systems or to require changes in command structure.

An MSP programming system according to the exemplary embodiment can represent a significant change when compared to previous MSP programming systems. Existing-system programming for speaker amplifier systems, executed from the MSP's own front panel, is, in many instances, entirely manual, so that while it fully supports the programming of a system's MSP, such a programming routine may in practice reach an operability limit as the number of speaker amplifiers becomes large. Manual-only programming routines for MSPs are in many instances virtually entirely lacking in the record keeping, dynamic configuration control, and user training and support functions. The added functions of the exemplary MSP increase the range of capabilities by allowing a user to transmit into the MSP extended sequences of commands that would be onerously complex and time consuming to enter by manual keystrokes.

The many features and advantages of the invention are apparent from the detailed specification, and, thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described; accordingly, all suitable modifications and equivalents may be resorted to that fall within the scope of the invention.

1. A master system panel, comprising:
an analog audio signal transmitter;
a digital signal transceiver; and
a command execution facility comprising a processor, wherein said command execution facility is capable of accepting and executing a command received via said transceiver.

2. The master system panel of claim 1, further comprising:
a set of software to control said command execution facility.

3. The master system panel of claim 1, further comprising:
an audio input port;
an audio amplifier; and
an audio output port.

4. The master system panel of claim 1, wherein said command execution facility further comprises nonvolatile data storage.

5. The master system panel of claim 1, further comprising:
a capability for manual input to the master system panel of at least one instruction;
an instruction to suspend normal operation;
a command execution facility for externally applied commands following suspension of normal master system panel operation; and
a command execution facility for normal operation following reception of an externally applied command to resume normal operation.

6. A programmable speaker amplifier control system, comprising:
a master system panel comprising:
an analog audio signal transmitter;
a digital signal transceiver; and
a command execution facility comprising a processor, wherein said command execution facility is capable of accepting and executing a command received via said transceiver;
a speaker amplifier; and
a communication subsystem interconnecting said master system panel and said speaker amplifier.

7. The programmable speaker amplifier system of claim 6, further comprising a set of commands to accept system panel configuration instructions by way of said communication subsystem.

8. The programmable speaker amplifier system of claim 6, wherein said software further comprises a set of commands to control at least one digitally enabled speaker amplifier.

9. The programmable speaker amplifier system of claim 6, further comprising a command to define the state of a relay that is an integral part of a speaker amplifier system element and bears an assignable unit number and device number.

10. The programmable speaker amplifier system of claim 6, further comprising at least one command to define the zone assignments for at least one digitally enabled speaker amplifier.

11. The programmable speaker amplifier system of claim 6, further comprising a command to assign a new address to a master system panel.

12. The programmable speaker amplifier system of claim 6, further comprising a command to define the master/satellite status of a speaker amplifier system panel.

13. The programmable speaker amplifier system of claim 6, further comprising a command to associate a control input switch closure line to a speaker amplifier system panel with a zone assignment.

14. The programmable speaker amplifier system of claim 6, further comprising a command to specify whether a speaker amplifier system panel is to operate in conjunction with a backup power source.

15. The programmable speaker amplifier system of claim 6, further comprising a command to acquire current contents of configuration memory in a speaker amplifier system panel.

16. The programmable speaker amplifier system of claim 6, further comprising a command to terminate external control, thereby restoring normal operation for the master system panel in a programmable speaker amplifier system.

17. The programmable speaker amplifier control system of claim 6, wherein said speaker amplifier further comprises:
an analog audio signal input port;
an amplifier to amplify signals impinging at said analog audio signal input port;
a power supply to convert electrical power from an available source to the form required for amplifier operation; and
a loudspeaker.

18. The programmable speaker amplifier system of claim 6, further comprising:
a digital communication input port;
a digital communication signal decoder;
a digital command interpreter;
a nonvolatile storage element; and
a digital reply generator.

19. The programmable speaker amplifier system of claim 6, further comprising:
an electronic switch under the control of said digital command interpreter; and
an electrical interconnect circuit permitting establishment and interruption of the signal path from said analog audio signal input port to said loudspeaker.

20. The programmable speaker amplifier system of claim 6, further comprising:
a first transceiver in said master system panel; and
a second transceiver in said speaker amplifier, capable of establishing bidirectional communication with said first transceiver.

21. The programmable speaker amplifier system of claim 6, further comprising a satellite system panel under the control of said master system panel.

22. The programmable speaker amplifier system of claim 6, further comprising a booster extending the physical and electrical range of said first transceiver.

23. The programmable speaker amplifier system of claim 6, wherein said communications subsystem further comprises an RS-485 bidirectional differential serial communications port and associated interface electronics.

24. The programmable speaker amplifier system of claim 6, wherein said communications subsystem further comprises an IEEE 802.3 Ethernet® bidirectional serial communications port and associated interface electronics.

25. A programmable speaker amplifier control system, comprising:
processing means for processing electronic signals;
communicating means for communicating between said processing means and a digitally enabled speaker amplifier; and
configuring means for configuring said processing means in response to externally applied signals.

26. The programmable speaker amplifier control system of claim 25, further comprising:
interrogating means for interrogating said digitally enabled speaker amplifier by an interrogation routine.

27. The programmable speaker amplifier control system of claim 25, further comprising:
recovering means for recovering system configuration information from automated records of the status of a system panel maintained in nonvolatile storage media.

28. A process for configuring a speaker amplifier system, comprising the steps of:
communicating between an external signal source and a system panel; and
configuring a system panel.

29. The process for configuring a speaker amplifier system of claim 28, further comprising the steps of:
interrogating a system panel with a command that causes the interrogated system panel to respond to the command by transmitting a report of its configuration; and
reading the response of a system panel so interrogated.

30. The process for configuring a speaker amplifier system of claim 28, further comprising the steps of:
displaying the response of a system panel to interrogation; and
storing the response of a system panel so interrogated.
